(19) United States
(12) Patent Application Publication
(10) Pub. No.: US 2013/0062104 A1
(43) Pub. Date: Mar. 14, 2013

(54) RESONANT MATERIAL LAYER APPARATUS, METHOD AND APPLICATIONS

(71) Applicants: Harold G. Craighead, Ithaca, NY (US); Jeevak M. Parpia, Ithaca, NY (US); Paul McEuen, Ithaca, NY (US); Jiwoong Park, Ithaca, NY (US); Jonathan S. Alden, Ithaca, NY (US); Robert A. Barton, Ithaca, NY (US); Bojan R. Ilic, Ithaca, NY (US); Carlos S. Ruiz-Vargas, Ithaca, NY (US); Arend M. van der Zande, Ithaca, NY (US)

(72) Inventors: Harold G. Craighead, Ithaca, NY (US); Jeevak M. Parpia, Ithaca, NY (US); Paul McEuen, Ithaca, NY (US); Jiwoong Park, Ithaca, NY (US); Jonathan S. Alden, Ithaca, NY (US); Robert A. Barton, Ithaca, NY (US); Bojan R. Ilic, Ithaca, NY (US); Carlos S. Ruiz-Vargas, Ithaca, NY (US); Arend M. van der Zande, Ithaca, NY (US)

(73) Assignee: Cornell University - Cornell Center for Technology Enterprise & Commercialization (CCTEC), Ithaca, NY (US)

(21) Appl. No.: 13/606,124

(22) Filed: Sep. 7, 2012

Related U.S. Application Data
(60) Provisional application No. 61/532,139, filed on Sep. 8, 2011.

(51) Int. Cl. B32B 1/06; H05K 1/02; B05D 5/00; H05K 1/11; B82Y 40/00

(52) U.S. Cl. 174/255; 428/34.1; 428/34.6; 427/58; 427/122; 977/734

(57) ABSTRACT

A resonant structure and a method for fabricating the resonant structure each include a substrate that includes at least one cavity. The resonant structure and the method for fabricating the resonant structure also include a resonant material layer located and formed over the substrate and at least in-part covering the at least one cavity. The resonant structure may comprise a graphene resonator structure.

### CROSS-REFERENCE TO RELATED APPLICATION

This application is related to, and derives priority from, U.S. Provisional Patent Application Ser. No. 61/532,139, filed 8 Sep. 2011, and titled Graphene Based Apparatus, Method and Applications, the content of which is incorporated herein fully by reference.

### STATEMENT OF GOVERNMENT INTEREST

The research that lead to the embodiments as described herein and the invention as claimed herein was funded by the United States National Science Foundation under grant number DMR 0520404 and grant number ECS 0335765. The United States Government has rights in the invention claimed herein.

### BACKGROUND

Graphene, which is a single layer of carbon atoms bonded in a hexagonal lattice, is a prototypical two-dimensional membrane material. Graphene has unparalleled strength, low mass per unit area, an ultrahigh aspect ratio and unusual electronic properties that make graphene an ideal candidate for nanoelectromechanical system (NEMS) applications.

Since graphene thus comprises a material with multiple desirable and unique properties, that provide for use of graphene within various applications, desirable are additional graphene based apparatus, methods and applications.

### SUMMARY

Embodiments provide a plurality of graphene material layer structures and a plurality of methods for fabricating the plurality of graphene material layer structures. The plurality of graphene material layer structures in accordance with the embodiments includes a substrate that includes at least one cavity, as well as at least one graphene material layer located over the substrate and covering at least in-part the at least one cavity. The embodiments contemplate that the at least one cavity may comprise a closed bottom cavity, or under certain circumstances of materials considerations comprise an open bottom cavity. The plurality of methods for fabricating the plurality of graphene material layer structures may provide for transfer of a patterned graphene material layer after patterning of the patterned graphene material layer from a larger graphene material layer.

Thus, the embodiments provide methods that may be used to produce large arrays of suspended, single-layer graphene material membrane resonators on arbitrary substrates using a graphene material that may be grown by chemical vapor deposition (CVD). Having many graphene material membranes located and formed over and/or upon a single substrate allows one to systematically study the mechanical resonance properties of single-layer graphene material layer resonators as a function of size, clamping geometry, temperature, and electrostatic tuning. And as well, such multiple graphene material membranes located and formed over and/or upon a single substrate also enables efficient manufacturing. One may find that the CVD graphene material produces tensioned, electrically conducting, highly tunable graphene resonators with properties equivalent to exfoliated graphene material. In addition, one may find that clamping of a graphene material layer membrane on all sides of a graphene material layer membrane when fabricating a graphene material layer resonator reduces a variation in resonance frequency and makes more predictable an electromechanical behavior of the graphene material layer resonator.

A particular structure in accordance with the embodiments includes a substrate including at least one enclosed bottom cavity. The particular structure also includes a plurality of resonant material layers located freely suspended over the substrate and at least in-part over the at least one enclosed bottom cavity.

Another particular structure in accordance with the embodiments includes a substrate including at least one open bottom cavity and comprising a material selected from the group consisting of semiconductor materials and dielectric materials. This other particular structure also includes at least one resonant material layer located freely suspended over the substrate and at least in-part over the at least one open bottom cavity.

Yet another particular structure in accordance with the embodiments includes a substrate including at least one cavity. This other particular structure also includes at least one resonant material layer located freely suspended over the substrate and at least in-part over the at least one cavity. This other particular structure also includes a direct bias electrical connection to one of the substrate and the at least one resonant material layer. This other particular structure also includes a modulated bias electrical connection to the other of the substrate and the at least one resonant material layer.

A particular method for fabricating a structure in accordance with the embodiments includes forming a resonant material layer upon a transfer substrate. This particular method also includes patterning the resonant material layer upon the transfer substrate to form a patterned resonant material layer upon the transfer substrate. This particular method also includes transferring the patterned resonant material layer to a second substrate.

Another particular method in accordance with the embodiments includes providing a substrate including a cavity. This other particular method also includes positioning over the substrate and at least in-part over the cavity a patterned resonant material layer patterned from a larger resonant material layer.

Within the context of the embodiments, a resonant material layer that is located or formed “freely suspended” over a substrate and at least in-part over at least one cavity is intended as a resonant material layer that is not laminated to any other layer at the point at which the resonant material layer is located or formed over the substrate and at least in-part over the at least one cavity.

Within the context of the embodiments, the terminology “over” is intended as a relative vertical disposition of an element within a described structure with respect to another element within the described structure, where the two described elements do not necessarily contact. In contrast, use of the terminology “upon” is intended as a relative vertical disposition of an element within a described structure with respect to another element within the described structure with an intention that the two elements contact.

### BRIEF DESCRIPTION OF THE DRAWINGS

The objects, features and advantages of the embodiments are understood within the context of the Detailed Description of the Embodiments, as set forth below. The Detailed Description of the embodiments is understood within the context of the accompanying drawings, that form a material part of this disclosure, wherein:

FIG. 1a and FIG. 1b show angled scanning electron microscopy images of suspended graphene material layer membranes in accordance with a first embodiment.

FIG. 1c shows an optical microscopy image of an array of suspended graphene material layer membranes in accordance with the first embodiment.

FIG. 2a to FIG. 2f show a series of graphs of measurements related to the suspended graphene material layer resonator structures in accordance with the first embodiment.

FIG. 3a to FIG. 3d show a series of images of measurements related to suspended graphene material layer resonator structures in accordance with a second embodiment.

FIG. 4a to FIG. 4f shows a series of angled scanning electron microscopy images and electrical measurements related to suspended graphene material layer resonator structures in accordance with a third embodiment.

FIG. 5 shows a graph of quality measurements for graphene material layer resonators in accordance with the embodiments.

FIG. 6 shows Raman spectra of CVD graphene: (a) as grown on copper foil; and (b) as a suspended membrane between gold electrodes.

FIG. 7 shows scanning electron microscopy images illustrating primary modes of failure in Type A graphene material layer membranes.

FIG. 8a shows DC electrical resistance versus back-gate voltage for a graphene material layer membrane in accordance with FIG. 4a.

FIG. 8b shows an electrical mixing measurement apparatus for electromechanical resonance measurements of a graphene material layer resonator in accordance with the embodiments.

FIG. 9a shows a scanning electron microscopy image of a circular graphene material layer resonator in accordance with a fourth embodiment.

FIG. 9b to FIG. 9e show a series of schematic cross-sectional diagrams illustrating the results of progressive stages in fabricating a circular graphene material layer resonator structure in accordance with the fourth embodiment.

FIG. 10 shows a series of diagrams illustrating resonant modes within a circular graphene material layer resonator in accordance with the fourth embodiment.

FIG. 11 shows a series of diagrams illustrating performance characteristics of a circular graphene material layer resonator in accordance with the fourth embodiment.

FIG. 12 shows a graph of quality factor as a function of frequency and diameter for a circular graphene material layer resonator in accordance with the fourth embodiment.

### DETAILED DESCRIPTION OF THE EMBODIMENTS

The embodiments provide a plurality of graphene material layer resonator structures, and related methods for fabricating the plurality of graphene material layer resonator structures. The foregoing graphene material layer resonator structures and related methods may be predicated upon a substrate including at least one cavity, and a graphene material layer located and formed over the substrate and covering at least in-part the at least one cavity. Particular graphene material layer resonator structures in accordance with the embodiments include open bottom cavity and closed bottom cavity graphene material layer resonator structures. Particular methods for fabricating the plurality of graphene material layer resonator structures include patterned graphene material layer transfer methods.

### I. General Considerations for Graphene Material Layer Resonator Structures and Related Material Layer Resonator Structures

While the embodiments are illustrated within the context of graphene material layer resonator structures and related methods, the embodiments are not necessarily intended to be so limited. Rather the embodiments contemplate resonator structures and related fabrication methods including but not limited to graphene, partially hydrogenated or fluorinated graphene, boronitride, borocarbonitride (i.e., BNC and BₓC_{y}N_{z},), thin film dicalcogenide and Bi₂Sr₂CaCu₂Oₓ resonant materials. As well, the embodiments also contemplate under particular conditions that resonant materials within a resonator structure may completely cover a particular cavity or alternatively incompletely cover a particular cavity.

With respect to the cavity, the embodiments contemplate that the cavity may comprise a shape selected from the group including but not limited to square, rectangle, polygonal, circular, elliptical and other flowing shapes. Typically and preferably, the cavity has area dimensions from about 100 to about 100,000 nanometers and depth dimensions from about 100 to about 10,000 nanometers.

### II. Rectangular Graphene Material Layer Resonator Structures

In accordance with the embodiments, and in order to fabricate rectangular resonator structures in accordance with the embodiments, one may start by using a chemical vapor deposition method to deposit a graphene layer supported upon a copper foil substrate, although copper substrates other than copper foil substrates may also be used. The graphene material layer deposited in accordance with the embodiments may be verified to be predominantly single-layer (>90%) with low disorder by Raman spectroscopy and scanning electron microscopy.

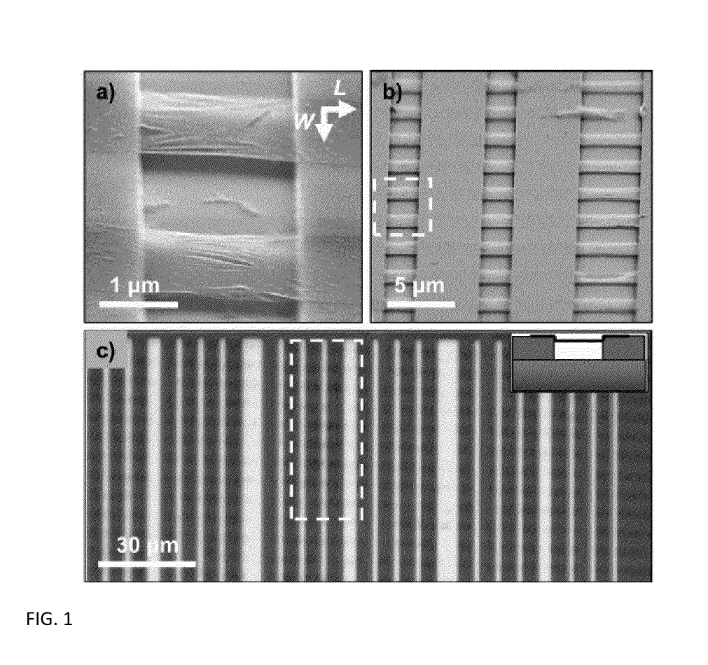

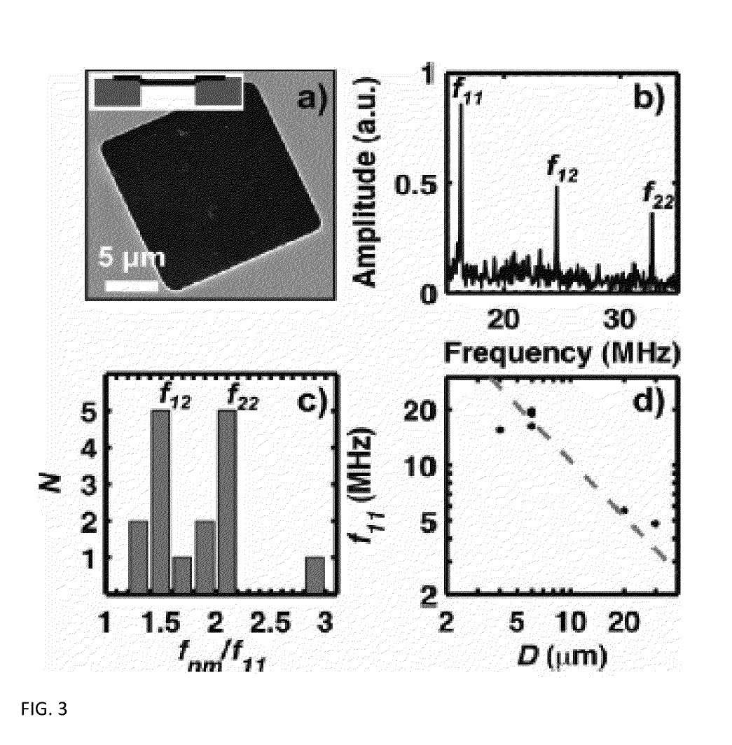

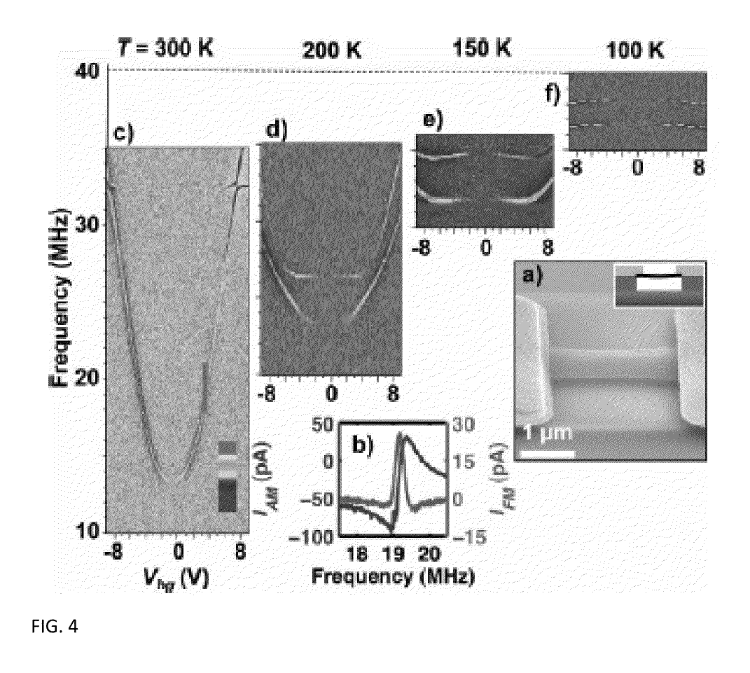

The core components for three different rectangular graphene material layer resonator structure geometries and graphene material layer resonator device geometries for graphene material layer resonators were fabricated as shown in FIG. 1a, FIG. 3a and FIG. 4a using variations on graphene material layer transfer techniques. Type A graphene material layer membranes (FIGS. 1a-c) consist of graphene material layer strips suspended over trenches and clamped at both ends of a particular graphene material layer strip (doubly clamped) by a van der Waals adhesion of a graphene strip to a substrate. Type A graphene material layer membranes were fabricated by patterning a larger graphene material layer into strips on a copper foil substrate with photolithography and oxygen plasma, and then transferring the patterned graphene material layer strips onto trenches on a 285 nm silicon oxide substrate. Type B graphene material layer membranes (FIG. 3a) are square graphene material layer membranes clamped on all sides. These membranes were fabricated by transferring unpatterned graphene material layers onto a suspended silicon nitride membrane with square holes. Type C graphene material layer membranes (FIG. 4a) are electrically contacted membranes suspended between two gold electrodes fabricated by transferring an unpatterned graphene material layer to a 285 nm silicon oxide substrate, patterning the graphene material layer into small bars, depositing gold electrodes on top, and suspending the graphene material layers by wet etching of an oxide out from underneath. Detailed fabrication procedures for all geometries are described below.

Within all approaches to forming suspended graphene material layer membranes, one may produce hundreds to hundreds of thousands of single-layer suspended graphene material layer membranes in each fabrication run, in accordance with the embodiments. For Type A graphene material layer resonator devices and Type C graphene material layer resonator devices, one may obtain yields of >80% for graphene membranes with L<3 μm and W<5 μm. For Type B graphene material layer resonator devices, one may obtain yields of >90% for membranes up to 5 μm on a side with lower yields for membranes up to 30 μm on a side.

The suspended graphene material layer membranes show complicated conformational structure, including small-scale (˜10 nm in amplitude) ripples such as those seen in FIG. 1a, and larger-scale (˜100 nm in amplitude) buckling of the membrane along the length and width. Ripples and buckling have also been observed in both exfoliated and epitaxial graphene material layer membranes due to in-plane tension, shear, or compression. The amount of rippling and buckling in graphene material layer resonator structures and graphene material layer resonator devices in accordance with the embodiments varies between neighboring membranes produced on a single chip, indicating that the tension/shear/compression in the graphene material layer membranes is variable. The degree to which this variability influences the graphene material layer resonator properties is addressed below. Finally, in larger membranes, occasional tears occur at mechanically weak grain boundaries between crystals in the CVD grown graphene resonator material.

To actuate and detect the mechanical resonance of the graphene membranes, first used was a resonance-modulated optical reflectance measurement. A particular graphene material layer membrane was actuated with a radio frequency (RF) modulated 405 nm CW laser, and the mechanical motion was detected using interferometry of the reflected light of a 633 nm helium-neon laser. All optical measurements were performed at room temperature in vacuum with p<5×10⁻⁵ ton.

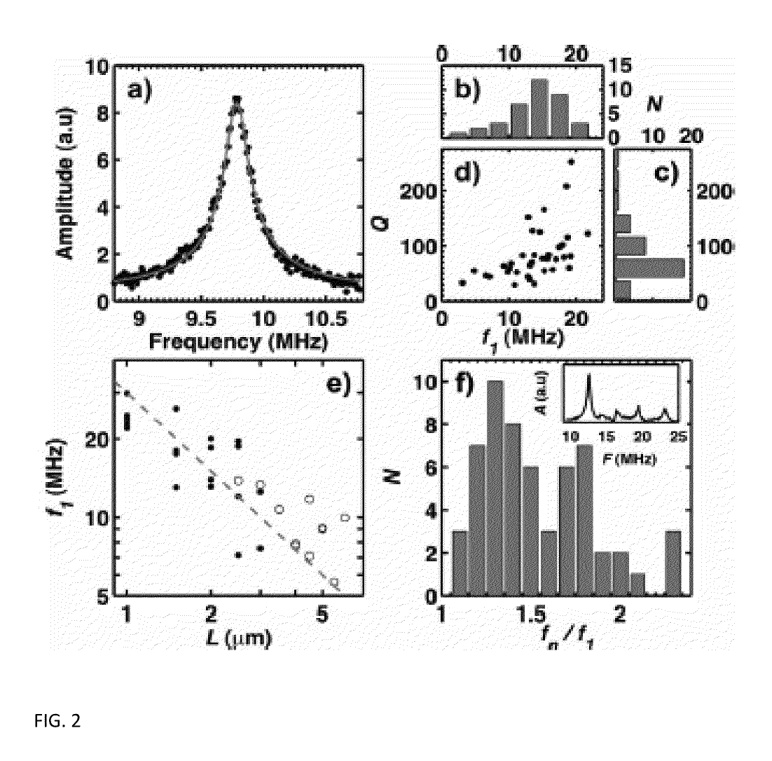

FIG. 2a is a plot of the fundamental mode for a Type A membrane of length L=2 μm and width W=3 μm. The resonance frequency is f₁=9.77 MHz and the quality factor is Q=52. FIGS. 2b-d show the frequency and quality factor of the fundamental mode for 38 identically patterned graphene membranes measured along a single trench. FIGS. 2b, c are histograms of the resonance frequencies and quality factors. There is a clear peak in the histogram at f₁˜15 MHz with a spread of 8 MHz. The quality factors range from 25-250 with a peak at 70. FIG. 2d shows that higher frequency is correlated with higher quality factor. These graphene resonators are nominally identical so the variation is due to either differences in adsorbed mass or the strain and conformational structure of the membranes.

FIG. 2e shows f₁ versus L for Type A doubly clamped graphene resonator membranes with L between 1 and 6 μm and W between 2.5 and 5 μm, plotted on a log-log scale. The resonance frequencies decrease with length and show no discernible dependence on the width. For reference, the dashed line shows an L⁻¹ dependence. The black dots represent graphene membranes without tears, while the squares represent partially torn membranes. Interestingly, the torn membranes show similar behavior to the untorn membranes.

The simplest model of a doubly clamped graphene membrane resonator is as a sheet under tension:

$${f}_{n} = \frac{n}{2 L} \sqrt{\frac{Yt}{{ρ}_{0}} \frac{ɛ}{α}}$$

where Yt=340 N/m and ρ₀=7.4×10⁻⁷ kg/m² are the inplane stiffness and density of single-layer graphene, n=1, 2, 3 . . . is the mode number, s is the in-plane strain, and α=ρₜₒₜₐₗ/ρ₀ is the adsorbed mass coefficient. Previous results have shown the ratio of the contamination mass to the membrane mass can be large, typically varying between 1 and 10. This model predicts an L⁻¹ scaling of the resonance frequencies with length, consistent with the data. From a best fit to the data in FIG. 2e, one may extract the average strain per absorbed mass ratio on the resonators of s/α˜10⁻⁵. This value is comparable to previously measured strains on exfoliated graphene membranes. The strain likely results from the self-tensioning of the graphene as the van der Waals attraction adheres the membrane to the walls of the trench, as shown schematically in the FIG. 1 inset.

The tensioned membrane model predicts a second harmonic at twice the frequency of the first. FIG. 2f shows all measured higher resonant modes of the identical devices, normalized by the fundamental mode frequency with one example spectrum in the inset. Instead of a peak at 2f₁, there is a broad distribution in frequencies with peaks around fₙ˜1.3 f₁ and 1.6 f₁. These peaks correspond with the second and third measured modes. These most likely correspond to transverse modes or edge modes in the resonator due to non-uniform strain in the resonator. Previous experiments have shown that local modes can exist at the edges exist in exfoliated graphene resonators and the frequencies of these modes are difficult to estimate without a detailed knowledge of the structure in the transverse direction.

To test the hypothesis that the transverse properties are important, one may fabricate and measure the resonance in the Type B graphene membranes shown in FIG. 3a, where the membrane is clamped on all sides and the transverse modes are identical to the longitudinal ones. FIG. 3b, c shows that one may observe higher resonant modes at frequencies approximately 1.5 and 2 times the fundamental. This is in good agreement with the expected values of f₂₁=1.58 f₁₁, and f₂₂=2f₁₁ predicted for a square membrane of uniform tension clamped on all sides

$${f}_{nm} = \frac{\sqrt{{n}^{2} + {m}^{2}}}{2 D} \sqrt{\frac{Yt}{{ρ}_{0}} \frac{S}{α}}$$

With the fully clamped membranes, the reproducibility is also improved with frequencies of 16.5, 18.8, 19.4, and 19.8 MHz measured for four nominally identical devices, a spread of less than 15%. The frequency also scales as approximately the inverse of the membrane dimension, as shown in FIG. 3d. The quality factors are also higher, Q>200; noise prevents a more accurate determination. Full clamping clearly improves the device reproducibility and quality factors over those observed in doubly clamped membranes, likely by eliminating soft degrees of freedom associated with the free edges.

Some of the most exciting properties of exfoliated graphene resonators are their ability to be actuated and detected electrically, their large voltage-tunable frequency range and their high quality factor at low temperature (Q˜10,000 for exfoliated graphene membranes at 4 K). These aspects of CVD graphene resonators were explored by fabricating the Type C, electrically contacted graphene membrane resonators shown in FIG. 4a. Transport measurements show these devices have mobilities of 1000-4000 cm²/V·s, similar to previous results on CVD graphene. Using a conventional electromechanical mixing measurement, one may actuate the resonators electrostatically and measure the motion using amplitude modulation (AM) or frequency modulation (FM) mixing. FIG. 4b shows the electrical mixing response versus drive frequency for AM (blue—upper curve on right) and FM (green—upper curve on left) mixing techniques with back gate voltage V_{bg}=3 V, and drive V_{RF}=7 mV. Both techniques yield a resonator frequency f₁=19.2 MHz and quality factor of Q=44 at this gate voltage.

FIG. 4c shows the FM mixing current as a function of the drive frequency and electrostatic gate voltage at room temperature. The resonance frequency increases by more than a factor of 2 for large V_{bg} and is symmetric around a minimum close to V_{bg}=0, very similar to the behavior previously reported for exfoliated graphene.

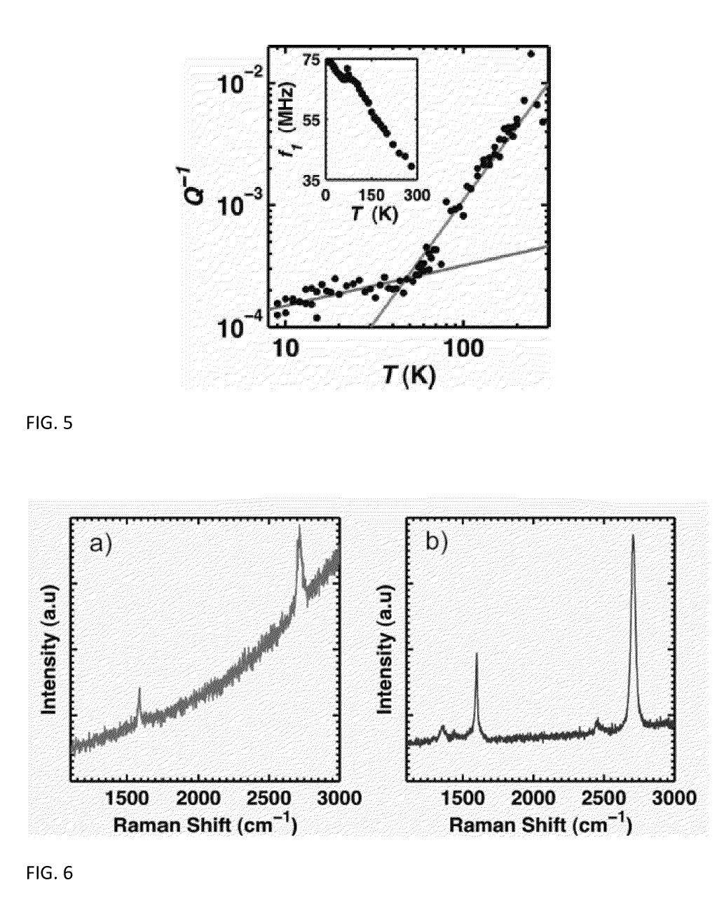

FIGS. 4 d-f show the tuning of the same resonance at T=200, 150, and 100 K. As the temperature is decreased the frequency of the resonator at V_{bg}=0 rises, while the dependence of the resonance frequency on V_{bg} becomes weaker, and even reverses sign at 100 K. The change of frequency tunability with temperature is due to changes in the tension of the graphene as it is cooled and is similar to that seen in exfoliated graphene resonators. FIG. 5 shows the inverse quality factor of a resonator versus temperature for a fixed V_{bg}=3 V. The inset shows the frequency versus temperature over the same temperature range. As the temperature is decreased, the quality factor rises dramatically from 150 at room temperature to 9000 at 9 K. This is comparable to the highest quality factors reported for graphene resonators at that temperature.

From FIG. 5, the inverse quality factor scales approximately as T^{α} where α=0.35+/−0.05 from 9 up to 40 K, and as T^{β} where β=2.3+/−0.1 from 40 K to room temperature. The temperature scaling is similar to what is found for exfoliated graphene resonators. Similar temperature dependence is also seen in carbon nanotube resonators. While there are many theories examining dissipation in these systems the observed behavior is still not understood.

The techniques described here provide a step toward practical graphene-based devices. This work shows that it is possible to fabricate large arrays of low mass, high aspect ratio, CVD-grown single-layer graphene membranes while maintaining the remarkable electronic and mechanical properties previously observed for exfoliated graphene. This is an important conclusion, demonstrating that the benefit of wafer-scale processing allowed by CVD graphene comes at little or no cost in mechanical resonator performance. One may further observe that clamping the membrane on all sides improves resonator performance and reproducibility. The wafer-scale production of low-mass, high-frequency, and highly tunable nanomechanical membrane resonators opens the way for applications in areas from sensing to signal processing.

### III. Circular Graphene Material Layer Resonator Structures

In addition to the nominally rectangular resonators fabricated in accordance with description above, the embodiments also provide that for circular graphene drum resonators fabricated by the same chemical vapor deposition (CVD) methods and transfer methods, the quality factor is linearly dependent on the diameter of the resonator. This observation may be used to produce resonators with Q as high as 2400+/−300 at room temperature. These circular drum resonators have RQ products as high as 14,000 nm⁻¹, which rivals that of the best membrane resonators otherwise available today. Measurements of quality factor for different resonant modes suggest that Q is only weakly dependent on modal frequency and is determined predominantly by the size of the membrane. Together, these observations offer new insights into the dissipation mechanisms underlying graphene resonator performance.

Membranes such as the one shown in FIG. 9a were fabricated following the procedure described above. Graphene was grown on copper foil by CVD. After a 30-50 nm thick layer of poly(methyl methacrylate) (PMMA) was spin-coated on the graphene to mediate transfer, the copper was dissolved in a ferric chloride-based etch (CE-200, Transene) and the graphene was rinsed in DI H₂O. Separately, a Si substrate coated with approx 300 nm thick Si-rich silicon nitride was back-etched using KOH to suspend a 2 mm×2 mm square nitride membrane. Then, using photolithography, circular holes were patterned in the nitride membrane with diameter 2-30 μm (FIG. 9b). Following the procedure outlined below, the graphene was transferred to the backside of this substrate from an H₂O bath (FIG. 9c). The graphene conformed to the substrate and adhered directly to the nitride membrane, covering many of the holes. After the graphene was allowed to dry in air, the PMMA was removed by decomposition at 350 C in air. This procedure resulted in suspended graphene drums with yields greater than 90% for holes 2 μm in diameter and as high as 25% for holes 30 μm in diameter. An example is shown in FIG. 9a, it is noted that localized contamination is visible on the surface of the graphene sheet. Transmission electron microscopy studies of graphene membranes prepared in an identical manner found that the bulk of the visible contamination was iron, oxygen, and carbon. However, the structural element of these resonators is monolayer graphene, as is evident from Raman spectroscopy as described below.

Finally, one may allow the front side of the nitride wafer to adhere to a blank piece of silicon. This step left graphene membranes up to 30 μm in diameter suspended on silicon nitride 300 nm above a silicon surface (see FIG. 9d, e). Fixing a nitride membrane against a substrate was a crucial step that enabled measurement of quality factor in this work. Surprisingly, one may find no membranes that stuck to the silicon backplane as a result of this step.

To detect the resonance of the graphene drums, one may use an interferometric method. Resonator motion may be monitored by a HeNe laser reflecting from the resonator and the silicon backplane; the interference between these two reflections changes when the resonator moves and thereby changes the total reflected light intensity. These changes are monitored by a fast photodiode connected to a spectrum analyzer. Resonator motion is actuated using a 405 nm amplitude-modulated diode laser (Picoquant, Berlin, Germany) that excites motion through photothermal expansion and contraction of the graphene membrane. All resonance measurements were performed in a vacuum chamber evacuated to pressures less than 6×10⁻³ torr, where viscous damping was found to be insignificant.

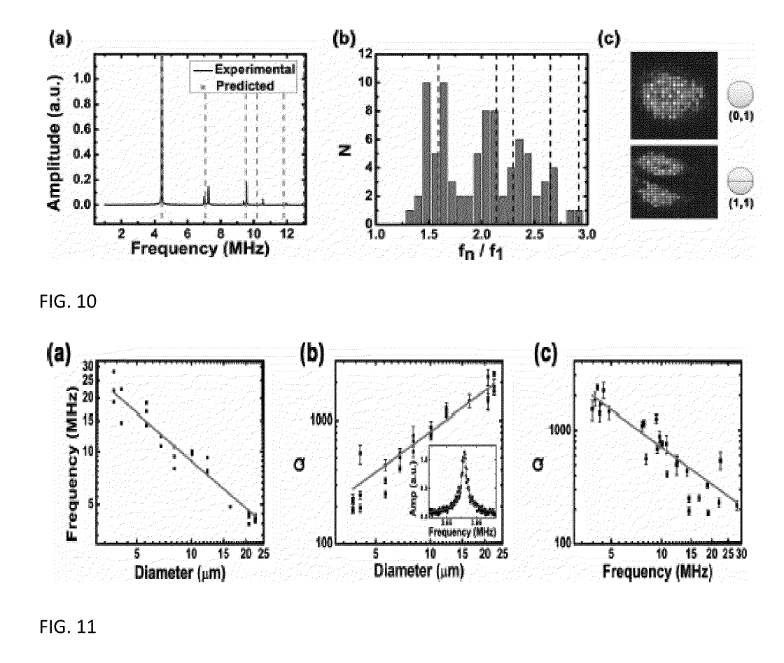

Both the spectra and fundamental modes of membranes of various sizes were investigated. Clamping the membranes on all sides made the distribution of higher resonance modes relative to the fundamental modes predictable. A spectrum from one membrane that falls particularly close to a predicted spectrum is shown in FIG. 10a. The dotted (red) lines show the predicted frequencies of all modes given the fundamental mode of the membrane (modes are expected at 1.59, 2.14, 2.30, 2.65, and 2.92 times the fundamental frequency). Multiple peaks often cluster around the predicted frequency of a given mode, as for the second and third modes in FIG. 10a. One may attribute these peaks to theoretically degenerate modes whose degeneracy has been lifted by asymmetries in either the surface contamination or stress profile of the membranes. FIG. 10b shows a histogram of the number of modes at a given multiple of the fundamental frequency for a set of 29 devices of various sizes. The peaks agree fairly well with theory. Measurements of the mode shapes of these circular membranes, obtained by measuring response amplitude as a function of laser position, confirm that the shapes of at least the first few modes are as predicted by the theory for circular membranes. Mode shape data for one membrane is presented in FIG. 10c. This behavior should be contrasted with previous measurements of doubly clamped beam resonators made from exfoliated graphene, which frequently displayed complicated, unpredictable mode shapes.

In addition to the well-behaved spectra of these devices, one may observe that the fundamental frequency as a function of device size was well described by a tensioned membrane model. In FIG. 11a is plotted the fundamental frequency as a function of diameter for the set of 29 devices examined in FIG. 10b. For circular membranes under tension, the fundamental frequency should follow

$$f = \frac{4.808}{2 π D} \sqrt{\frac{Yt ɛ}{ρα}}$$

where D is the diameter, Yt is the in-plane Young's modulus, F is the in-plane density of graphene, ε is the strain, and R is a density multiplier used to quantify the amount of mass contaminating the device (FR is defined to be the in-plane density of the resonator including both graphene and any additional mass). A fit of the data in FIG. 11a shows that frequency is roughly proportional to inverse diameter as predicted by this equation. If one assumes the known values for graphene, Yt=340 N/m and F=7.4×10⁻¹⁶ g μm⁻², one may find that ε/R about 10⁻⁵. Since the density of the resonator is at least that of graphene (R>1), the minimum possible strain in the graphene is 10⁻⁵, which is comparable to the strain in previously fabricated graphene resonators. The tension is thought to be caused by the adherence of the graphene to the sidewalls of the nitride by van der Waals forces, a model supported by the consistency of the strain across many devices.

The quality factor of each device can be extracted from the full width half-maximum of each Lorentzian resonance peak. A plot of the quality factor of fundamental modes as a function of diameter is shown in FIG. 11b. There is a clear dependence of quality factor on resonator diameter, and fitting this data to Q˜D⁶² yields β=1.1+/−0.1. The highest quality factor observed was 2400+/−300 for a device with 22.5 μm diameter (FIG. 11b, inset). One may note that there was one 30 μm device measured in this data set, but it is not shown in these plots because it contained a significant rip. The quality factor of this ripped device was measured to be 1030+/−150.

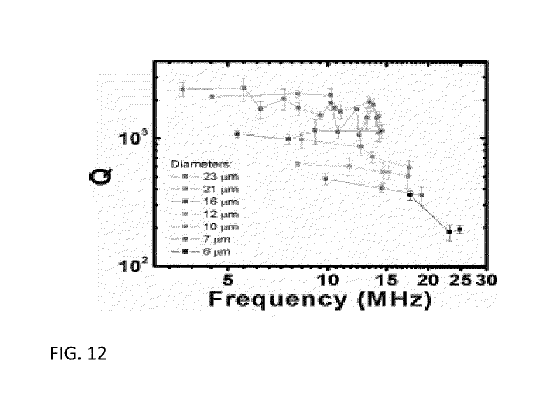

As a result of the dependence of both Q and frequency on diameter, Q must also be related to frequency, as shown in FIG. 11c. To disentangle the effects of diameter and frequency on quality factor, one may measure the quality factor of higher order modes of many membranes. FIG. 12 shows the results of these measurements. With the possible exception of the smallest membranes, quality factor is not highly dependent on modal frequency. Certainly, the variation of dissipation with frequency between modes is less than linear for all but the smallest membrane. One may therefore surmise that size, rather than frequency, is the essential factor determining the Q of the membrane.

To compare the dissipation in graphene to that in other mechanical resonators, the discussion may return to the RQ product. It is a relevant measure of the performance of NEMS against the common problem of surface-related losses. Taking the thickness of graphene to be 0.335 nm, the highest RQ product of a graphene resonator measured here is roughly 14,000 nm⁻¹. In contrast, single crystal silicon nanomechanical devices achieve at most RQ in the range 200-3000 nm⁻¹. High stress silicon nitride resonators, which were recently discovered to have exceptionally high RQ products, have achieved RQ products of at most 100,000 nm⁻¹ for a 0.5 mm×0.5 mm×50 nm square membrane. Like graphene membrane quality factors, however, silicon nitride quality factors also depend on the size of the resonator. Thus, it is also relevant to compare the present results to those of high stress nitride membranes of similar size, like the 15 μm diameter, 110 nm thick drumhead resonators reported in Wilson-Rae, I.; Barton, R. A.; Verbridge, S. S.; Southworth, D. R.; Ilic, B.; Craighead, H. G.; Parpia, J. M. Phys. Rev. Lett. 2011, 106 (4), No. 047205 (Q=15 000; RQ=270 nm⁻¹). That is, in drum resonators of comparable diameters, graphene has a quality factor to thickness ratio higher than that of high stress silicon nitride.

The origin of the dissipation in graphene resonators is currently unknown; however, the observations herein provide some insight. One may first discuss why one observes high Q from the devices in this work and not for previously fabricated monolayer graphene doubly clamped beams, which have been studied as a function of length up to 6 μm with no reported dependence on size. Although the fabrication methods used here are less invasive than those used to fabricate doubly clamped beams from CVD graphene (the graphene here is exposed only to PMMA, copper etchant, and water), we do not believe that better treatment is responsible for the improved quality factor, since monolayer graphene resonators made by exfoliation, the cleanest possible method, also had low Q at room temperature. More likely, the improvement in quality factor is due to fixing the membranes on all sides, which, according to simulations, improves Q by eliminating “spurious edge modes.” The reproducible spectra of membranes in accordance with the embodiments compared to those of doubly clamped membranes lends further credence to this theory.

Even if fixing all sides of the membrane eliminates dissipation due to edge modes, one may be confronting another source of dissipation that is dependent on size and not strongly dependent on modal frequency. One may consider several candidate sources of this dissipation in light of these observations. One may find that the contribution from thermoelastic damping, which one may calculate by treating the graphene as a clamped circular plate, is too small to be important for resonators in accordance with the embodiments. The dependence of the dissipation on size, or, equivalently, perimeter to area ratio, suggests that anchor losses may play a role in graphene. However, a recent model of losses from phonon tunneling into a substrate gives dissipation estimates that are orders of magnitude too low, and it predicts a complicated behavior of quality factor as a function of mode that is not observed within the context of the embodiments. A more probable candidate is surface-related effects, which seem likely to play a role for these ultrathin resonators given the increase in dissipation of most NEMS with increased surface to volume ratio. One may note that both the size dependence and the modal frequency dependence of circular graphene membranes are qualitatively similar to the dissipation in doubly clamped silicon nitride beams, which was found to be related to local strain in the resonators and possibly to coupling of the strain with surface defects. Further modeling is required to examine these dissipation mechanisms. Measurements of the dissipation as a function of temperature should also prove revealing.

The high RQ products observed for resonators in accordance with the embodiments demonstrate that large graphene resonators have the potential to be very sensitive to mass per unit area. A commercial quartz crystal microbalance can resolve approximately 400 pg cm⁻², and a study of the dynamic range achieved with the instant readout technique, a graphene resonator 12 μm in diameter could resolve 3 pg cm⁻² (4 ag total mass). Further progress in biological functionalization should enable specific detection with this sensitivity, which would be useful for biomedical sensing. Also, the limit of force sensitivity for these resonators is dF=(4k_{eff} k_{B}T/ωQ)^{1/2}, where, where k_{eff} is the effective spring constant, k_{B} is the Boltzmann constant, T is temperature, and ω is frequency. For a highest quality factor resonator in accordance with the embodiments, this limit is dF˜200 aN/Hz^{1/2}, which is high for room temperature operation. Additionally, because k_{eff}˜m_{eff}ω² is independent of diameter, and because we find empirically that ωQ is independent of diameter, this limit of force sensitivity is independent of the resonator area. Therefore, large-area graphene membrane resonators should enable very sensitive measurements of force per unit area.

This study provides information about dissipation in monolayer graphene resonators that was not accessible before the recent advances in graphene fabrication. The embodiments show that quality factor in tensile graphene drums is proportional to the diameter of the membrane. For the largest embodied resonators, one may observe RQ products as high as 14,000 nm⁻¹, which is better than that of even high stress silicon nitride resonators of comparable sizes. It therefore appears that relative to its low mass, graphene offers an excellent quality factor in addition to its high frequency and high electrical conductivity, making it an ideal material for NEMS.

### IV. Experimental

In accordance with the embodiments, the following process steps enumerate graphene growth and transfer process sequence for forming rectangular graphene material layer resonators in accordance with the first three of the foregoing embodiments.

### 1. Graphene Growth and Transfer:

### A. CVD Growth Furnace Setup:

The chemical vapor deposition of graphene material is done in a 1 inch diameter low pressure, temperature controlled, gas flow furnace. Gasses include UHP argon, hydrogen, and methane, with flows controlled by an automatic flow controller. Low pressure is achieved using an oil pump with a cold trap. The gas flow attachments are tightly clamped to prevent atmospheric contamination. Gas pressure should be <10 mtorr with no gas flowing and ˜1 ton with gas flowing.

### B. Growth Procedure:

### Part 1: Preparing for Growth

1. Use Alfa Aesar 0.025 mm, 99.8% pure copper foils.
2. Cut out 1.5 cm squares, notch the edge to indicate orientation, and press between glass slides to flatten.
   Note: During the entire growth and transfer process, care must be taken to keep the copper foils as flat as possible. Crumpled foils lead to cracked graphene membranes and poor transfers.
3. Treat the foil with the following order of solvent dips: acetone (10 sec), water, acetic acid (10 minutes), water, acetone (10 sec), IPA (10 sec).
4. Use low flow nitrogen gun to gently remove remaining IPA.
5. Load 3-5 copper foils into CVD furnace.
6. Pump system down to a base pressure under 10 millitorr.

### Part 2: Graphene Growth

1. After base pressure is achieved, flow 6 sccm of hydrogen. The pressure should rise to about 120 millitorr.
2. Turn furnace on to reach 1000 C.
3. Anneal foil in hydrogen at 1000 C for 10 minutes.
4. After anneal, flow 157 sccm methane for 13 minutes. Pressure should rise to 5.5 torr.
5. Let grow for 13 minutes.
6. Cool slowly over 2 hours.
7. Replace gas with 200 sccm argon for final 2 minutes, and let argon re-pressurize the tube.

### C. Graphene Transfer Procedure:

1. Use 8% anisole-PMMA, spin PMMA onto one side of foil (keep track of which side) at 4000 RPM for 60 seconds. PMMA should be ˜500 nm thick. Do not bake.
2. Etch graphene off of other side of copper foil using oxygen plasma.
3. Pour 1 M ferric chloride copper-etch solution.
4. Carefully place foil onto the surface of the copper-etch solution with PMMA side up. PMMA is hydrophilic so foil will float on acid surface.
5. Let copper etch away completely ˜30 minutes.
6. Scoop PMMA-graphene membrane into DI water. Membrane should float on the surface of water, with the PMMA side up, and the graphene side down. Keep membrane flat to avoid cracking graphene.
7. Repeat 6 times into fresh DI water.
8. Scoop membrane out of liquid one more time with desired final substrate. The graphene should be in contact with the surface.
9. Let chip and membrane dry ˜1 day.
10. Soak chip in dichloromethane for ˜4 hours to remove PMMA.
11. Rinse with acetone, then IPA.
12. If suspended devices are desired, use a critical point dry to get chip out of solution.

### 2. Suspended Graphene Fabrication Procedure:

For Type A devices, patterned were 3 um wide graphene ribbons on the copper foil using contact lithography and a 20 second oxygen plasma etch. The photoresist was then cleaned off the graphene by sonicating the foil in acetone for 1 minute, then the foil was soaked for 10 minutes and sonicated again for 1 minute. Following the transfer procedure described above, one may transfer the patterned graphene onto a PMMA membrane, then transfer the PMMA/graphene membrane onto the surface of a silicon wafer with 285 nm of oxide and a patterned array of trenches with length of 1-8 um and depth of 285 nm. Finally one may dissolve the PMMA in dichloromethane and critical point dry the chip to preserve the suspended structures.

For Type B devices, one may transfer unpatterned CVD graphene on a 50 nm thick PMMA membrane onto a 200-nm thick suspended silicon nitride membrane patterned with square holes. After letting the PMMA graphene membrane dry, one may anneal a chip at 300 C in air for 2 hours. The PMMA gently bakes off the chip leaving the graphene freely suspended in a liquid free process.

For Type C devices, one may transfer un-patterned CVD graphene onto a degenerately doped silicon wafer coated with 285 nm of silicon oxide. One may then pattern the deposited graphene into an array of rectangles using oxygen plasma, and clean the remaining photoresist off by soaking the sample in acetone for 4 hours, and then anneal the sample in argon/hydrogen 0.8/0.2 SLM gas flow for 2 hours. 2 nm/150 nm thick titanium/gold electrodes may be deposited on top of the patterned graphene, using buffered hydrofluoric acid etch (BOE 6:1) to completely remove the oxide under the graphene, and then critical point dry the sample.

### 3. Sample Quality:

The number of graphene layers and the sample quality may be verified using Raman Spectroscopy. FIG. 6 shows the Raman shift for graphene (a) on the copper foil directly after growth and (b) suspended between gold electrodes on a Type C device after all processing. One may see an increase in the disorder of the graphene as a larger D peak after processing. The disorder is likely either due to resist contamination or at the edges of the membrane during the shaping step of the graphene.

### 4. Tearing:

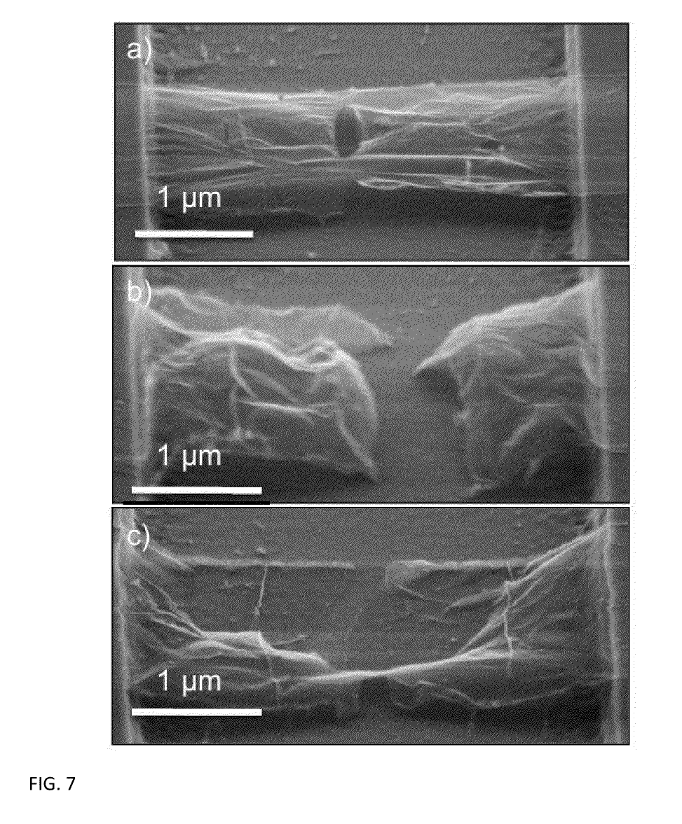

FIG. 7 shows the three primary modes of failure for suspended graphene membranes: (a) partial tearing of the membrane, (b) complete tearing of the membrane, and (c) stick down on to the substrate.

### 5. Suspended Graphene Transport Measurements:

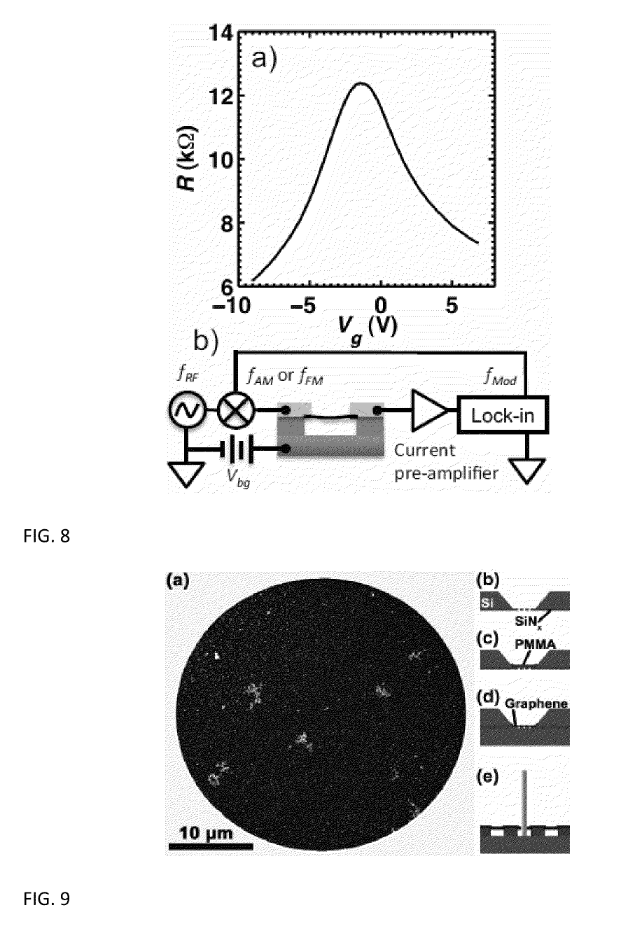

FIG. 8 shows the electrical resistance versus back gate voltage of the suspended graphene membrane shown in FIG. 1c. One may use the equation

$$μ ∼ A \text{/} {C}_{bg} \frac{d G}{d {V}_{bg}}$$

to extract a lower bound on the graphene mobility of 4000 cm2/v-sec.

### 6. Electrical Resonance Measurements:

The discussion of mixing presented here is intended to compare mixing measurements in accordance with the embodiments with known techniques. For extensive derivations of the AM and FM mixing techniques for graphene and carbon nanotube resonators, one may consult conventional disclosures.

As shown in FIG. 8b, one may apply a voltage V_{bg} to a back-gate, and a radio frequency voltage V_{RF} to a drain of a resonator device. The gate capacitance C_{bg} causes the graphene membrane to be electrostatically attracted to the back-gate.

$${F}_{bg} = \frac{1}{2} {C}_{bg}^{′} {V}_{bg}^{2} + {C}_{bg}^{′} {V}_{bg} {V}_{RF} ( t )$$

The static voltage tensions the graphene membrane and the RF voltage drives the sheet to resonate. By symmetry, the RF voltage can be applied either to the gate or to the drain with similar results. To detect the motion of the resonator, one may take advantage of the semimetal properties of graphene, where the conductance of the graphene sheet G(V_{bg}, C_{bg}) depends on both the applied voltage and gate capacitance. If the gate voltage changes, or the graphene moves, the conductance changes.

$$d G = \frac{\partial G}{\partial {V}_{bg}} d {V}_{bg} + \frac{\partial G}{\partial z} d z$$

However, it is difficult to directly measure the changes in conductance due to motion at RF because the signal is small and there is a large parallel capacitance in the system. One may employ two related mixing techniques to bring the signal down to low frequency. Instead of applying a pure RF signal at the drain, one may apply either an amplitude-modulated signal or a frequency-modulated signal

$${V}_{AM} ( t ) = \frac{{V}_{RF 0}}{2} ( 1 + m sin ( 2 π {f}_{Mod} t ) ) sin ( 2 π {f}_{RF} t )$$

$$or$$

$${V}_{FM} ( t ) = {V}_{RF 0} sin ( 2 π ( {f}_{RF} + {f}_{Δ} sin ( 2 π {f}_{Mod} t ) ) t )$$

where V_{RF0} is the drive amplitude of the resonator operating at radio frequency f_{RF}. The RF voltage is modulated at a frequency f_{Mod}=1 kHz. The amplitude of modulation is typically m=1 for AM, and f_{δ}=50 kHz for FM measurements. One may measure the current through the graphene with a lock-in amplifier at f_{Mod}. The total current measured using AM or FM mixing is

$${I}_{AM} ( {f}_{Mod} ) = \frac{1}{2} \frac{d G}{d q} ( {C}_{bg} {V}_{RF 0} + {C}_{bg}^{′} {V}_{bg} Re ( {z}^{*} ( {f}_{RF} ) ) ) {V}_{RF 0} cos ( 2 π {f}_{mod} t )$$

$$or$$

$${I}_{FM} ( {f}_{Mod} ) = \frac{1}{2} \frac{d G}{d q} {C}_{bg}^{′} {V}_{bg} {V}_{RF 0} \frac{d Re ( {z}^{*} ( {f}_{RF} ) )}{d {f}_{RF}} {f}_{Δ} cos ( 2 π {f}_{mod} t )$$

where dG/dq is the transconductance of the graphene, z*(f_{RF}) is the complex amplitude of motion, and Re(z*(f_{RF})) is the real component of the complex amplitude that is in phase with the drive force Re z*(z*(f_{RF})=z cos Φ.

There are two important observations to make about the mixing equations. First, the AM mixing current has a background due to the pure electrical mixing in the graphene, while the FM mixing current does not. Second, assuming a simple harmonic resonator response to drive, the AM mixing technique gives a heartbeat shaped mixing response and the FM mixing technique gives a mode shape that is proportional to the derivative of the AM mode shape d Re(z*(f_{RF}))/d f_{RF}. These are the mode shapes measured in FIG. 4b.

All references, including publications, patent applications, and patents cited herein are hereby incorporated by reference in their entireties to the same extent as if each reference was individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening.

The recitation of ranges of values herein are merely intended to serve as a shorthand method of referring individually to each separate value falling within the range, unless otherwise indicated herein, and each separate value is incorporated into the specification as if it was individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate embodiments of the invention and does not impose a limitation on the scope of the invention unless otherwise claimed.

No language in the specification should be construed as indicating any non-claimed element as essential to the practice of the invention.

It will be apparent to those skilled in the art that various modifications and variations can be made to the present invention without departing from the spirit and scope of the invention. There is no intention to limit the invention to the specific form or forms disclosed, but on the contrary, the intention is to cover all modifications, alternative constructions, and equivalents falling within the spirit and scope of the invention, as defined in the appended claims. Thus, it is intended that the present invention cover the modifications and variations of this invention provided they come within the scope of the appended claims and their equivalents.

What is claimed is:

1. A structure comprising:
a substrate including at least one enclosed bottom cavity; and
a plurality of resonant material layers located freely suspended over the substrate and at least in-part over the at least one enclosed bottom cavity.

2. The structure of claim 1 wherein the substrate comprises at least one material selected from the group consisting of conductor materials, semiconductor materials and dielectric materials.

3. The structure of claim 1 wherein the cavity comprises a shape selected from the group consisting of square, rectangle, polygonal, circular, elliptical and other flowing shapes.

4. The structure of claim 1 wherein the plurality of resonant material layers comprise at least one resonant material selected from the group consisting of graphene, partially hydrogenated or fluorinated graphene, BNC, BₓC_{y}N_{z}, thin film dichalcogenides, and Bi₂Sr₂CaCu₂Oₓ.

5. The structure of claim 1 wherein the plurality of resonant material layers comprises a graphene resonant material.

6. A structure comprising:
a substrate including at least one open bottom cavity and comprising a material selected from the group consisting of semiconductor materials and dielectric materials;
at least one resonant material layer located freely suspended over the substrate and at least in-part over the at least one open bottom cavity.

7. The structure of claim 6 wherein the cavity comprises a shape selected from the group consisting of square, rectangle, polygonal, circular, elliptical and other flowing shapes.

8. The structure of claim 6 wherein the at least one resonant material layer comprises a resonant material selected from the group consisting of graphene, partially hydrogenated or fluorinated graphene, BNC, BₓC_{y}N_{z}, thin film dichalcogenides, and Bi₂Sr₂CaCu₂Oₓ.

9. The structure of claim 6 wherein the at least one resonant material layer comprises a graphene resonant material.

10. The structure of claim 6 wherein the at least one resonant material layer covers completely the at least one cavity.

11. The structure of claim 6 wherein the at least one resonant material layer covers incompletely the at least one cavity.

12. A structure comprising:
a substrate including at least one cavity;
at least one resonant material layer located freely suspended over the substrate and at least in-part over the at least one cavity;
a direct bias electrical connection to one of the substrate and the at least one resonant material layer; and
a modulated bias electrical connection to other of the substrate and the at least one resonant material layer.

13. The structure of claim 12 wherein the cavity comprises a shape selected from the group consisting of square, rectangle, polygonal, circular, elliptical and other flowing shapes.

14. The structure of claim 12 wherein the at least one resonant material layer comprises a resonant material selected from the group consisting of graphene, partially hydrogenated or fluorinated graphene, BNC, BₓC_{y}N_{z}, thin film dichalcogenides, and Bi₂Sr₂CaCu₂Oₓ.

15. The structure of claim 12 wherein the at least one resonant material layer comprises a graphene resonant material.

16. The structure of claim 12 wherein the at least one resonant material layer covers completely the at least one cavity.

17. The structure of claim 12 wherein the at least one resonant material layer covers incompletely the at least one cavity.

18. A method for fabricating a structure comprising:
forming a resonant material layer upon a transfer substrate;
patterning the resonant material layer upon the transfer substrate to form a patterned resonant material layer upon the transfer substrate; and
transferring the patterned resonant material layer to a second substrate.

19. The method of claim 18 wherein the resonant material layer comprises a resonant material selected from the group consisting of graphene, partially hydrogenated or fluorinated graphene, BNC, BₓC_{y}N_{z}, thin film dichalcogenides, and Bi₂Sr₂CaCu₂Oₓ.

20. The method of claim 18 wherein:
the at least one resonant material layer comprises a graphene resonant material; and
the transfer substrate comprises copper.

21. The method of claim 18 wherein the second substrate is a topographic substrate.

22. A method for fabricating a structure comprising:
providing a substrate including a cavity; and
positioning over the substrate and at least in-part over the cavity a patterned resonant material layer patterned from a larger resonant material layer.

23. The method of claim 22 wherein the cavity comprises a shape selected from the group consisting of square, rectangle, polygonal, circular, elliptical and other flowing shapes

24. The method of claim 22 wherein the patterned resonant material layer comprises a resonant material selected from the group consisting of graphene, partially hydrogenated or fluorinated graphene, BNC, BₓC_{y}N_{z}, thin film dichalcogenides, and Bi₂Sr₂CaCu₂Oₓ.

25. The method of claim 22 wherein the patterned resonant material layer comprises graphene.

26. The method of claim 22 wherein the positioning the patterned resonant material layer is undertaken using a layer transfer method that uses a transfer substrate.
